(19) United States
(12) Patent Application Publication
(10) Pub. No.: US 2011/0079883 A1
(43) Pub. Date: Apr. 7, 2011

(54) FERROELECTRIC THIN FILM

(75) Inventors: MIKIO SHIMADA, KAWASAKI-SHI (JP); TOSHIAKI AIBA, FUJISAWA-SHI (JP); TOSHIHIRO IFUKU, YOKOHAMA-SHI (JP); JUMPEI HAYASHI, YOKOHAMA-SHI (JP); MAKOTO KUBOTA, YOKOHAMA-SHI (JP); HIROSHI FUNAKUBO, YOKOHAMA-SHI (JP); YUICHI SHIMAKAWA, KYOTO-SHI (JP); MASAKI AZUMA, KYOTO-SHI (JP); YOSHITAKA NAKAMURA, KYOTO-SHI (JP)

(73) Assignees: CANON KABUSHIKI KAISHA, Tokyo (JP); TOKYO INSTITUTE OF TECHNOLOGY, Tokyo (JP); KYOTO UNIVERSITY, Kyoto-shi (JP)

(21) Appl. No.: 12/889,684

(22) Filed: Sep. 24, 2010

(30) Foreign Application Priority Data
Oct. 1, 2009 (JP) 2009-229914

(51) Int. Cl. H01L 49/02

(52) U.S. Cl. 257/627; 257/E49.004

(57) ABSTRACT

Provided is a ferroelectric thin film formed on a substrate and having an amount of remanent polarization increased in its entirety. The ferroelectric thin film contains a perovskite-type metal oxide formed on a substrate, the ferroelectric thin film containing a column group formed of multiple columns each formed of a spinel-type metal oxide, in which the column group is in a state of standing in a direction perpendicular to a surface of the substrate, or in a state of slanting at a slant angle in a range of −10° or more to +10° or less with respect to the perpendicular direction.

### BACKGROUND OF THE INVENTION

1. Field of the Invention

The present invention relates to a ferroelectric thin film, in particular, a ferroelectric thin film containing a column group formed of a spinel-type metal oxide and having an increased amount of remanent polarization.

2. Description of the Related Art

Ferroelectric materials are generally lead-based ceramics such as a lead zirconate titanate (hereinafter referred to as “PZT”) having a perovskite type structure.

However, the PZT contains lead at an A site of its perovskite lattice. Accordingly, an influence of the lead component on the environment has been perceived as a problem. To cope with the problem, a ferroelectric material using a perovskite-type oxide containing no lead has been proposed.

A representative lead-free ferroelectric material is BiFeO₃ (hereinafter referred to as “BFO”) as a perovskite-type metal oxide. For example, Japanese Patent Application Laid-Open No. 2007-287739 discloses a BFO-based thin film material containing lanthanum at an A site. The BFO thin film is a good ferroelectric substance, and has been reported to have a large amount of remanent polarization measured at a low temperature. However, BFO involves the following problem. That is, the insulating property of BFO under a room temperature environment is low, and hence an applied voltage for causing piezoelectric strain cannot be increased.

Japanese Patent Application Laid-Open No. 2005-011931 discloses an approach involving substituting a B site of BFO with Co at a ratio of 1 at. % to 10 at. % (hereinafter referred to as “BFCO”) as an attempt to improve the ferroelectric characteristic of a memory device using the BFO thin film.

However, general BFO and BFCO thin films each have an amount of remanent polarization of about 20 to 60 μC/cm², which does not reach a value enough for any such thin film to supplant a PZT material.

The inventors of the present invention understand a factor for the foregoing as described below. The lattice constant of a BFCO thin film can be adjusted by lattice matching with a substrate so that a good ferroelectric property may be obtained. At an upper portion of the film distant from the substrate, however, a fine lattice structure changes owing to stress relaxation, and hence an optimum lattice constant is not obtained. As a result, the amount of remanent polarization reduces.

The present invention has been made in view of such background art, and provides a ferroelectric thin film formed on a substrate and having an amount of remanent polarization increased in its entirety.

### SUMMARY OF THE INVENTION

A ferroelectric thin film, which solves the above-mentioned problems, contains a perovskite-type metal oxide formed on a substrate, the ferroelectric thin film including multiple columns each formed of a spinel-type metal oxide, the multiple columns being formed in the ferroelectric thin film, in which each of the columns is in a state of standing in a direction perpendicular to a surface of the substrate, or in a state of slanting at a slant angle in a range of −10° or more to +10° or less with respect to the perpendicular direction.

According to the present invention, there can be provided a ferroelectric thin film formed on a substrate and having an amount of remanent polarization increased in its entirety.

Further features of the present invention will become apparent from the following description of exemplary embodiments with reference to the attached drawings.

### BRIEF DESCRIPTION OF THE DRAWINGS

FIG. 1A is a schematic longitudinal sectional view illustrating an example of an embodiment of a ferroelectric thin film of the present invention.

FIG. 1B is a schematic plan view illustrating an example of the embodiment of the ferroelectric thin film of the present invention.

FIG. 2 is a schematic view illustrating the direction in which a column group in the ferroelectric thin film of the present invention is oriented.

FIG. 3 is a transmission electron microscope image (lattice image) and FFT images for a section of a ferroelectric thin film produced in Example 1 of the present invention.

FIG. 4 is a transmission electron microscope image (lattice image) and FFT images for a plane of the ferroelectric thin film produced in Example 1 of the present invention.

FIG. 5 is a graph illustrating the P-E hysteresis curves of the ferroelectric thin film of Example 1 of the present invention and a ferroelectric thin film of Comparative Example 1 in which a column group largely slanted.

FIG. 6 is a graph illustrating a relationship between a magnetization and an applied magnetic field for the ferroelectric thin film of Example 1 of the present invention.

### DESCRIPTION OF THE EMBODIMENTS

Hereinafter, an embodiment of the present invention is described in detail. In the following description, the term “column” is used for describing a substance having a “columnar structure” formed on a thin film.

A ferroelectric thin film according to the present invention is a ferroelectric thin film containing a perovskite-type metal oxide formed on a substrate, and is characterized in that: the ferroelectric thin film has a column group formed of multiple columns each formed of a spinel-type metal oxide; and the column group is oriented in the direction perpendicular to the surface of the substrate or a slant direction slanting at a slant angle in the range of −10° or more to +10° or less with respect to the perpendicular direction.

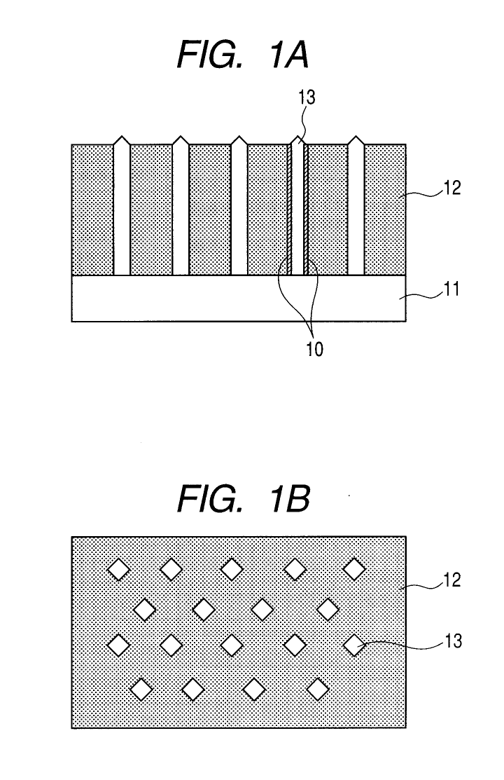

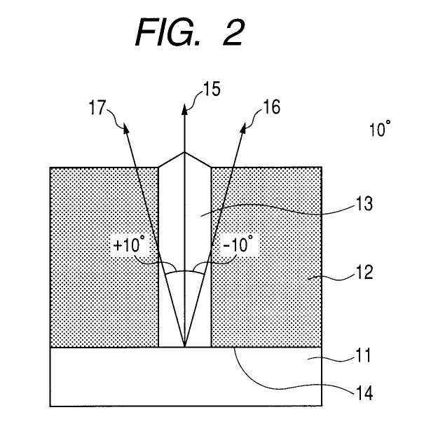

FIG. 1A is a schematic longitudinal sectional view illustrating an example of an embodiment of the ferroelectric thin film of the present invention. FIG. 1B is a schematic plan view illustrating an example of the embodiment of the ferroelectric thin film of the present invention. FIG. 2 is a schematic view illustrating the direction in which the column group in the ferroelectric thin film of the present invention is oriented. In FIG. 1A, the ferroelectric thin film according to the present invention is formed of a ferroelectric thin film 12 containing a perovskite-type metal oxide formed on a substrate 11, and a column group 13 formed of multiple columns each formed of a spinel-type metal oxide is formed in the ferroelectric thin film 12. The column group 13 is arrayed while being oriented. As illustrated in FIG. 2, the direction in which the columns are each oriented is a direction 15 perpendicular to a substrate surface 14, or falls within a range between slant directions 16 and 17 slanting at slant angles of −10° or more to +10° or less with respect to the perpendicular direction. In FIG. 1A, the column group contacts a (hk0) surface 10 of the ferroelectric thin film. FIG. 1A as a sectional view illustrates with emphasis only on part of the (hk0) surface of the ferroelectric thin film. In actuality, however, the outer peripheral portion of any other column not illustrated with emphasis also contacts at the (hk0) surface.

The ferroelectric thin film of the present invention formed of the above-mentioned constitution maintains a crystal structure comparable to that in the vicinity of the substrate at any one of its sites such as an upper portion of the thin film. As a result, the amount of remanent polarization of the ferroelectric thin film can be increased.

The perovskite-type metal oxide is generally represented by a chemical formula ABO₃. Elements A and B occupy specific positions of a unit cell called an A site and a B site, respectively in the forms of ions. In the case of a unit cell of a cubic crystal system, the element A is placed at an apex of the cube and the element B is placed at the body center of the cube. The O element occupies a face-centered position as an anion of oxygen.

The spinel-type metal oxide is generally represented by a chemical formula AB₂O₄. The O element forms face-centered cubic lattice as an anion of oxygen. The elements A and B account for one eighth of the center of tetrahedron formed by oxygen (tetrahedral site) and a half of the center of octahedron formed by oxygen (octahedral site), respectively in the forms of ions.

The perovskite type structure and the spinel type structure can be distinguished from each other by observation with a transmission electron microscope (hereinafter represented as “TEM”). For example, an electron diffraction pattern is acquired from a region to be noted, and the pattern is checked against a diffraction pattern calculated from a crystal structure model. Thus, a crystal structure can be identified.

The perovskite type structure and the spinel type structure can be distinguished from each other with a high-resolution TEM image (hereinafter represented as “lattice image”) as well. The lattice image illustrates a periodic contrast corresponding to the periodic structure of a crystal. Applying fast fourier transform to the lattice image, the fourier power spectrum corresponding to the electron diffraction pattern is obtained (hereinafter represented as “FFT image”). As in the case of the electron diffraction pattern described above, the crystal structure can be identified by analyzing the FFT image.

The perovskite-type metal oxide in the present invention is preferably selected from materials each having ferroelectricity in itself. Examples of the materials include BaTiO₃, Ba(Zr,Ti)O₃, SrTiO₃, BiFeO₃, and Bi(Fe,Co)O₃. Of those, Bi(Fe,Co)O₃ and BiFeO₃ are preferred, and Bi(Fe,Co)O₃ is more preferred.

The control of a crystal structure and a lattice constant is important in improving the ferroelectric property of a perovskite-type ferroelectric material. Accordingly, the ferroelectric thin film is formed on condition that a substrate that shows good lattice constant matching with the ferroelectric material is selected. However, an effect of the substrate weakens as the thickness of the ferroelectric thin film increases, and hence structural relaxation is apt to occur. As a result, the structure which is equivalent to that in the vicinity of the substrate cannot be maintained at the upper portion of the thin film, and hence the ferroelectric property reduces.

When the column group formed of the multiple columns each formed of the spinel-type metal oxide is caused to exist in the ferroelectric thin film, a stress is generated in the film by a pile-group effect. As a result, structural relaxation from the substrate of the ferroelectric thin film toward a film surface direction is suppressed. That is, a lattice constant in the film surface direction is maintained, and hence an improving effect on the ferroelectricity is obtained.

In addition, the perovskite-type ferroelectric material generally has a lattice constant ratio between a c-axis and an a-axis (c/a) of 1.00 or more to 1.02 or less. The lattice constant of the spinel type structure may be excessively large for the a-axis of the perovskite-type ferroelectric material, but shows good lattice matching for its c-axis. The presence of a spinel-type column group in the ferroelectric thin film exerts the following effect. That is, the lattice constant in the c-axis of the perovskite is maintained, and hence good ferroelectricity is maintained.

The ferroelectric thin film of the present invention and the column group in the ferroelectric thin film contact each other mainly at the (hk0) plane of the ferroelectric thin film, and the column group is oriented at the (hk0) plane of the ferroelectric thin film.

The phrase “contact each other mainly at the (hk0) plane” as used herein refers to a state where 80% or more of the contact plane of the column group contacts at the (hk0) plane of the ferroelectric thin film. An approach to specifying the index of the contact plane, which is not limited, is, for example, observation with a TEM. The contact plane can be specified by: tilting a sample so that the contact plane may be edge-on (the contact plane and the incident electron beam direction may be parallel to each other); and analyzing an electron diffraction pattern in this case. The contact surface can be similarly specified by analyzing the FFT image obtained from the lattice image.

When the ferroelectric thin film and the column group contact each other at a plane except the (hk0) plane, that is, a plane not parallel to the c-axis, the spinel type structure must show lattice matching for each of both the a-axis and c-axis of the perovskite type structure. The foregoing case is not desirable because such matching may not be established in a cubic spinel type structure.

As described above, the presence of the spinel-type column group enables the maintenance of the optimum ratio c/a of the ferroelectric thin film not only in the vicinity of the substrate but also in the entirety of the film. As a result, the ferroelectric thin film shows a large amount of remanent polarization.

In addition, the ferroelectric thin film and the column group are preferably oriented toward a (001) plane when the crystal system is regarded as a pseudo-cubic crystal, that is, (001) plane by representation of pseudo-cubic.

The orientation states of the ferroelectric thin film and the column group can be easily identified from the peak intensity and the diffraction angle in X-ray diffraction measurement generally employed for a crystal thin film (such as a 20/0 method). In the case of, for example, a diffraction chart obtained from the ferroelectric thin film in the present invention whose (001) plane is oriented in its thickness direction, the intensity of a diffraction peak at the angle corresponding to the (001) plane is extremely large as compared with the sum of the intensities of peaks detected at angles corresponding to the other plane.

When the column group is uniformly present in the direction perpendicular to the substrate, an effect of the column group is improved. For example, the case where the group is oriented toward a (111) plane is not preferred because each column becomes oblique with respect to the substrate in order that the ferroelectric thin film and the column group may contact each other at the (hk0) plane. At the same time, the case is not preferred because columns in crystallographically equivalent directions slanting by 90° (that is, columns whose orientations are not uniform) are present.

In the present invention, the column group is preferably oriented in the direction perpendicular to the surface of the substrate or a slant direction at a slant angle in the range of −10° or more to +10° or less with respect to the perpendicular direction. The slant angle is obtained by the cross sectional TEM observation. The point at which a column and the substrate contact each other, and the point of the column exposed from the surface of the ferroelectric thin film are connected with a straight line. The slant angle is obtained by measuring an angle formed between the straight line and the line perpendicular to the substrate.

The slant angle may be −10° or more to +10° or less, or preferably −5° or more to +5° or less. A slant angle of 0° corresponds to the direction perpendicular to the surface of the substrate. The case where the column group slants at a slant angle of more than 10° is not preferred because the column group contacts the ferroelectric thin film at a (441) plane.

In addition, the column group preferably has an average circle-equivalent diameter of 10 nm or more to 30 nm or less. The term “circle-equivalent diameter” as used herein refers to the diameter of a circle having the same area as that of an object. A circle-equivalent diameter of the column group in excess of 30 nm is not preferred because of the following reason. That is, the a-axis of the spinel type structure may not show lattice matching with the a-axis of the perovskite type structure, and hence strain to be introduced becomes large. On the other hand, a circle-equivalent diameter of the column group of less than 10 nm is not preferred because a column of the column group cannot resist the internal stress of the film and hence bends.

The ferroelectric thin film has a thickness of desirably 50 nm or more to 10,000 nm or less, or preferably 100 nm or more to 5,000 nm or less. When the thickness is less than 50 nm, the insulation resistance of the film may be poor. On the other hand, when the thickness exceeds 10,000 nm, it becomes difficult to maintain the structure of the ferroelectric thin film.

The length in the thickness direction of the column group is preferably equal to or larger than the thickness of the ferroelectric thin film. When the length of the column group is smaller than the thickness of the ferroelectric thin film, a lattice matching effect exerted by contact between each column and the ferroelectric thin film is limited, and hence an effect of the present invention is exerted only partially.

The ferroelectric thin film preferably contains the column group so that the column group may have a surface density of 1×10¹⁴ columns/m² or more to 1×10¹⁵ columns/m² or less. When the surface density is less than 1×10¹⁴ columns/m², a distance between columns enlarges, and hence the pile-group effect of the columns is not sufficiently exerted at a site positioned at an intermediate distance from each column. On the other hand, when the surface density is excessively large, or specifically exceeds 1×10¹⁵ columns/m², the amount of the ferroelectric thin film itself reduces, and hence the ferroelectric property of the entire film reduces.

The surface density can be calculated by TEM observation of a sample obtained by thinning the ferroelectric thin film and the column group in the film surface direction.

Alternatively, the surface density can be calculated by surface observation of a protruding portion of the column group from the ferroelectric thin film without thinning. That is, a surface observation apparatus such as a scanning electron microscope (SEM) or an atomic force microscope (AFM) has only to be used.

In addition, the diameter distribution of the column group in the thickness direction in the ferroelectric thin film is preferably 50% or less. The term “diameter” as used herein refers to the width of a column measured as described below. A section is taken in the direction perpendicular to the substrate, and the width is measured in the direction parallel to the substrate in the section.

As described above, the effect of the present invention strongly depends on the diameters of the column group. In order that a uniform effect may be exerted in the thickness direction of the ferroelectric thin film (a distribution in the thickness direction may be eliminated), the diameter of each column desirably shows no variation in the thickness direction (when attention is paid to one column, its diameter desirably shows no change in the midst of the column).

The term “diameter distribution” as used herein means a histogram obtained as described below. Attention is paid to one column, measurement points are set at an equal interval along the thickness direction of the ferroelectric thin film, and the diameter of the column is measured at each of the points. In addition, the phrase “diameter distribution is 50% or less” means that the lower limit and upper limit of the histogram fall within the range of its mode±50%.

The histogram is obtained by the cross sectional TEM observation. The histogram is created by measuring diameters along the thickness direction at an interval sufficiently fine as compared with a change in diameter of the column group (such as an interval of 5 nm).

The content of the column group in the ferroelectric thin film of the present invention is 5 to 30%, or preferably about 7 to 15% in terms of a volume fraction. The content is calculated from the circle-equivalent diameter and the surface density on the assumption that the diameters of the columns do not largely change with the thickness.

In addition, the column group in the present invention is formed of multiple columns, and each column is formed of a single crystal.

The effect of the present invention is based on lattice matching between the spinel type structure and the perovskite type structure, and such a macrostructure that the column group is present in the ferroelectric thin film. Therefore, the effect of the present invention, which is not limited by the composition of a material of which each of the column group and the ferroelectric thin film is formed, is particularly effective in the case of the following composition.

The composition of each of the columns of which the column group is formed is preferably formed of a compound represented by the following general formula (1).

Co₃₋ₓFeₓO₄ (1)

(In the formula, x satisfies a relationship of 0≦x≦2.)

A Co.Fe-based oxide adopts a spinel type structure over a wide composition region. For example, Co₃O₄ (a=0.808 nm), CoFe₂O₄ (a=0.837 nm), and Fe₃O₄ (a=0.840 nm) each adopt a spinel type structure. Further, the oxide adopts nonstoichiometric composition by substitution between Fe and Co, and its lattice constant changes in association with the composition. That is, the lattice constant can be adjusted by changing the composition of each of Co and Fe so that the oxide may show lattice matching with the ferroelectric thin film.

In addition, the composition of the ferroelectric thin film is preferably formed of a compound represented by the following general formula (2).

Bi_{y}(Fe_{1-z}Co_{z})O₃ (2)

(In the formula, y satisfies a relationship of 0.95≦y≦1.25 and z satisfies a relationship of 0<z≦0.30.)

When y is smaller than 0.95, Bi insufficiency is responsible for a defective site, thereby adversely affecting the insulation property of the thin film. On the other hand, when y is larger than 1.25, excess bismuth oxide precipitates at a grain boundary, and the precipitation may be a cause for a current leak at the time of the application of a high voltage. In addition, z ranges from more than 0 to 0.30 or less, and the range means that the thin film is a BFCO film in which Fe is partly substituted with Co. A larger piezoelectric property than that of a BFO thin film can be expected by virtue of the size effect of Co on Fe at the B site of the perovskite. It should be noted that, when z exceeds 0.3, the piezoelectric property and the insulation property may be lost because the solid dissolution of Co in the perovskite becomes difficult.

In addition, the composition of the ferroelectric thin film is preferably formed of a compound represented by the following general formula (3).

Bi_{y}FeO₃ (3)

(In the formula, y satisfies a relationship of 0.95≦y≦1.25.)

Although the composition is defined with reference to oxygen composition in each of the general formulae (1) to (3), the definition is for convenience, and does not exclude any material containing an oxygen vacancy.

A method of producing the ferroelectric thin film of the present invention is not particularly limited. Although the order in which the column group and the ferroelectric thin film are formed on the substrate is not limited either, the group and the thin film are preferably formed at the same time.

A method of forming the column group and the ferroelectric thin film on the substrate at the same time is, for example, a sputtering method. In order that the growth nucleus of each column may be formed by the sputtering method, target composition is preferably adjusted so as to be in a state of being easily subjected to phase separation. In addition, sputtering power and a substrate temperature must be controlled in order that the nucleus of each column may stably grow. Sputtered atoms that have reached the substrate diffuse on the surface of the film, and are then fixed on the surface. Whether the nucleus grows depends on the magnitude relation between a driving force for the diffusion and a trap effect exerted by the nucleus of each column. Excess kinetic energy at the time of the collision with the substrate and the substrate temperature largely contribute to the diffusion phenomenon in this case.

The diameter of each column is controlled by a film deposition rate. When the film deposition rate is small, the nucleus of the column largely grows in the film surface direction at the initial stage of the film deposition, and hence the diameter becomes large. On the other hand, when the film deposition rate is large, the nucleus of the column cannot sufficiently grow in the film surface direction at the initial stage of the film deposition, and hence the diameter becomes small.

In order that an oriented ferroelectric thin film may be obtained, a substrate with its lattice size controlled has only to be used. A conductive layer as an electrode may be provided for the surface of the substrate. A usable substrate is, for example, a single crystal substrate formed of magnesium oxide or strontium titanate. A substrate of a multilayer constitution obtained by laminating those materials may also be used.

### EXAMPLE 1

Hereinafter, the present invention is described more specifically by way of examples with reference to drawings and a table.

Description is given by using a ferroelectric thin film illustrated in each of FIGS. 1A and 1B.

The ferroelectric thin film 12 and the column group 13 formed of a spinel-type metal oxide are formed on the substrate 11 by a sputtering method. (100)La—SrTiO₃ is used as the substrate 11. The ferroelectric thin film 12 and the column group 13 are formed by simultaneous progress of film deposition and phase separation. Here, when a film deposition rate is small, the diameter of the column group becomes excessively large. In addition, the column group grows, which has a (111) plane as a surface, because that is stable plane in a spinel type structure. In view of the foregoing, in order that the film deposition rate may be increased, the film deposition is performed while an oxygen partial pressure is increased.

A green compact target was used as a sputtering target. The green compact target was obtained as described below. Bi₂O₃, Fe₂O₃, and Co₃O₄ were mixed so that their composition might be (110 to 140):70:30 in terms of a molar ratio. Thus, a mixture was obtained. The mixture was subjected to press molding so as to have a diameter of 101.6 mm (4 inches) and a thickness of 4 mm. Thus, the target was obtained. Bi₂O₃ was incorporated in an excessive amount as compared with its stoichiometric composition because of its high volatility.

The (100)La—SrTiO₃ substrate was heated for 30 minutes while a heating temperature was set to 600 to 700° C. After that, an Ar gas and an O₂ gas were introduced, an RF power source was turned on, and pre-sputtering was initiated. In this case, a ratio between Ar and O₂ ranged from 2:3 to 1:10. In other words, the partial pressure of O₂ was made larger than that of Ar. After the pre-sputtering had been performed with the above-mentioned sputtering target for 10 minutes, main sputtering was initiated. Film deposition was performed while a gas pressure ranged from 5 Pa to 13.3 Pa and sputter power ranged from 0.5 W/cm² to 4 W/cm². The film deposition was performed for 180 minutes. Thus, a sample having a thickness of 120 nm to 200 nm was produced.

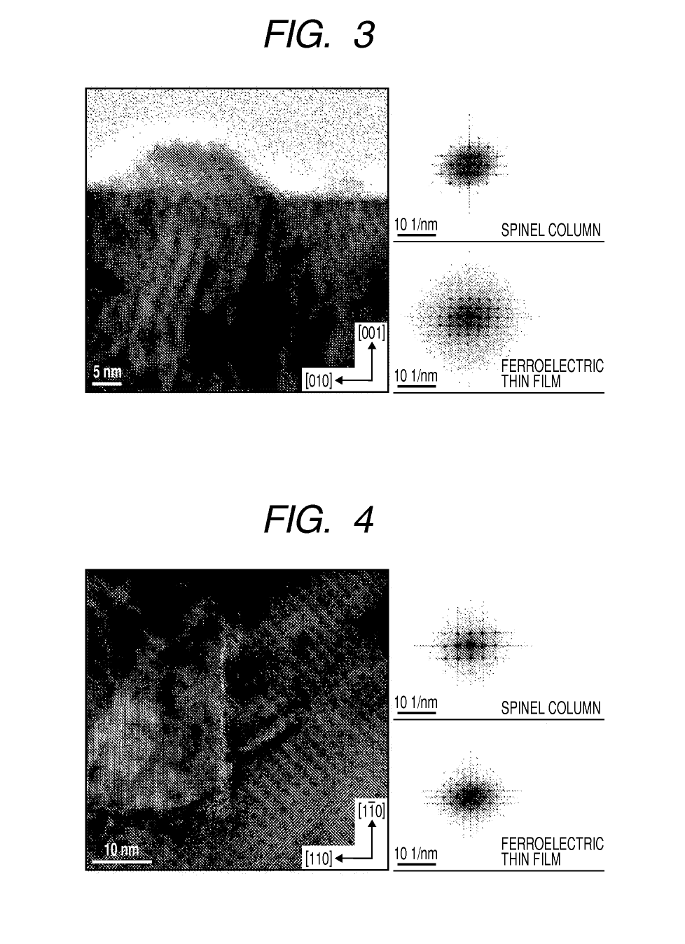

FIG. 3 is a transmission electron microscope image (lattice image) and FFT images for a section of the ferroelectric thin film produced in Example 1 of the present invention. It can be observed that the column group is present in the ferroelectric thin film and protrudes from the ferroelectric thin film. The FFT images are obtained from the columns and the ferroelectric thin film (provided that white and black colors are reversely displayed). It can be confirmed from the FFT images that the column group and the ferroelectric thin film adopt a spinel type structure and a perovskite type structure, respectively, and are oriented.

In addition, it can be found that the column group protrudes from the surface of the ferroelectric thin film and that the length of the column group is larger than the thickness of the ferroelectric thin film.

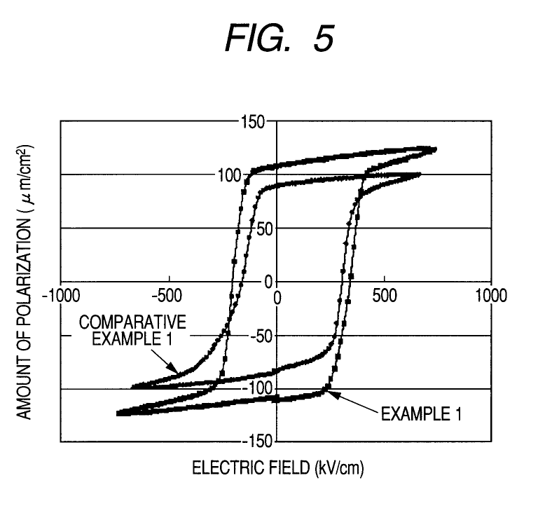

FIG. 4 is a transmission electron microscope image (lattice image) and FFT images for a plane of the ferroelectric thin film produced in Example 1 of the present invention. The FFT images are obtained from the columns and the ferroelectric thin film (provided that white and black colors are reversely displayed). It can be confirmed that the column group and the ferroelectric thin film contact each other at a (110) surface, that is, a (hk0) plane. Further, it can be confirmed that the ferroelectric thin film and the column group are oriented at (001) plane by representation of pseudo-cubic.

In addition, the average circle-equivalent diameter and surface density of the column group measured from the plane view TEM image of the ferroelectric thin film according to the present invention are about 22 nm and 3.0×10¹⁴ columns/m², respectively.

The column group formed of a spinel-type metal oxide is a magnetic substance, and has a transition point at around 200 K when its magnetization-temperature characteristics are measured. It can be conceived from the result that the composition of the column group formed of a spinel-type metal oxide is “Fe:Co=20:80.” In addition, the composition of the column group formed of a spinel-type metal oxide measured by electron energy loss spectroscopy (EELS) is “Fe:Co=19:81.” In other words, a result similar to that of the magnetization measurement is obtained. The foregoing shows that the column group is such that x is 0.57 or more to 0.60 or less in a compositional formula Co₃₋ₓFeₓO₄.

Meanwhile, a result obtained by the measurement of the composition of the ferroelectric thin film by EELS was that Co composition was 9%. In other words, the composition of the ferroelectric thin film portion was Bi(Fe_{0.91}Co_{0.09})O₃.

### COMPARATIVE EXAMPLE 1

The (100)La—SrTiO₃ substrate was heated for 30 minutes while a heating temperature was set to 600 to 700° C. After that, an Ar gas and an O₂ gas were introduced, an RF power source was turned on, and pre-sputtering was initiated. In this case, a ratio between Ar and O₂ ranged from 20:1 to 10:9. In other words, the partial pressure of Ar was made larger than that of O₂. After the pre-sputtering had been performed with the above-mentioned sputtering target for 10 minutes, main sputtering was initiated. Film deposition was performed while a gas pressure ranged from 5 Pa to 13.3 Pa and sputter power ranged from 0.5 W/cm² to 4 W/cm². The film deposition was performed for 180 minutes. Thus, a sample having a thickness of 120 nm to 200 nm was produced.

Here, the column group in the BFCO ferroelectric thin film obtained in Example 1 was evaluated for its slant angles with a TEM image. As a result, the slant angles ranged from 0° to 3°. In addition, the column group in the BFCO ferroelectric thin film obtained in Comparative Example 1 was similarly evaluated for its slant angles with a TEM image. As a result, the slant angles ranged from 15° to 45°.

FIG. 5 illustrates the P-E hysteresis curve of the BFCO ferroelectric thin film of Example 1 according to the present invention. The measurement was performed under an environment having a temperature of −60° C. and a pressure of 10⁻² Pa.

FIG. 5 illustrates data on the BFCO ferroelectric thin film of Comparative Example 1 as well.

As described above, the ferroelectric thin film of the present invention having a slant angle of the column group of −10° or more to +10° or less is found to show a large amount of remanent polarization. A remanent polarization is desirably large in an application such as a ferroelectric memory.

### EXAMPLE 2

A BiFeO₃ ferroelectric film containing a column group with CoFe₂O₄ composition and having a thickness of 200 nm to 300 nm as Example 2 was produced in the same manner as in Example 1 except that the composition of the green compact target was changed to “Bi₂O₃:Fe₂O₃:Co₃O₄=(110 to 140):80:20” in terms of a molar ratio. The column group was evaluated from a sectional TEM image (lattice image) and an FFT image in the same manner as in Example 1.

As a result, it was confirmed that the column group and the ferroelectric thin film contact each other at a (110) surface, that is, a (hk0) plane. Further, it was confirmed that the ferroelectric thin film and the column group are oriented at (001) plane by representation of pseudo-cubic. An average circle-equivalent diameter of the column group was about 14 nm and a surface density of the column group was about 5.0×10¹⁴ columns/m².

### COMPARATIVE EXAMPLE 2

A BiFeO₃ ferroelectric film free of any column group and having a thickness of 200 nm as Comparative Example 2 was formed in the same manner as in Example 1 except that the composition of the green compact target was changed to “Bi₂O₃:Fe₂O₃=(110 to 140):100” in terms of a molar ratio. No column group was confirmed from a sectional TEM image.

Table 1 shows the remanent polarizations of the ferroelectric thin films and the slant angles of the spinel column group represented by the examples and comparative examples. The remanent polarizations were each determined by P-E hysteresis curve measurement. In other words, the following hysteresis curve peculiar to a ferroelectric material was observed. In short, when the ferroelectric thin film of the present invention was provided with an electrode and the magnitude of an external electric field to be applied was changed positively and negatively, spontaneous polarization was inverted. Table 1 shows a remanent polarization (Pr) at an electric field of zero in the hysteresis curve.

TABLE 1

| | Remanent | Slant angle of |
|---|---|---|
| | polarization | column group |
| | (μC/cm²) | (degrees) |
| Example 1 | 110 | 0 to 3 |
| Example 2 | 100 | 0 to 4 |
| Comparative Example 1 | 85 | 15 to 45 |
| Comparative Example 2 | 90 | No columns |

The ferroelectric films of the examples of the present invention each containing a column group were films having good ferroelectric properties with a remanent polarization higher than those of the comparative examples by 5 μC/cm² or more.

The foregoing examples and comparative examples have elucidated that a spinel column group contacting at the (hk0) surface of a ferroelectric thin film significantly increases the remanent polarization of a perovskite-type metal oxide.

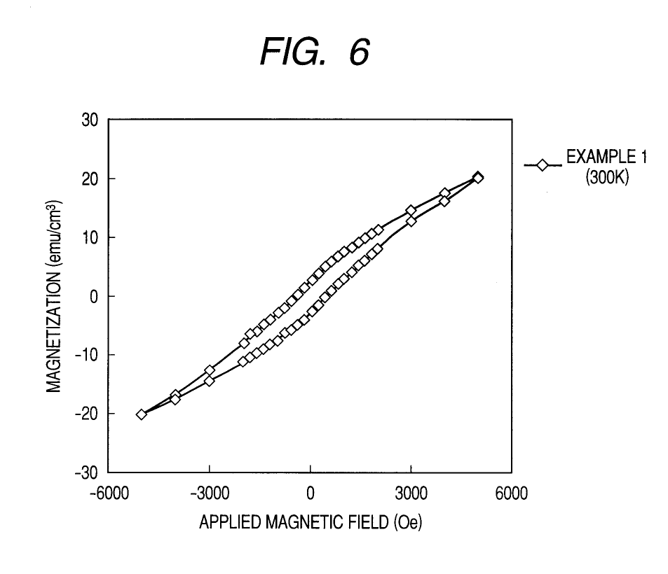

The ferroelectric thin film of Example 1 was subjected to magnetization measurement. The measurement temperature was room temperature (300 K) and a superconducting quantum interference devices (SQUID)-type, high-sensitivity magnetization measurement instrument was used. FIG. 6 illustrates the results of the measurement.

FIG. 6 shows that a remanent magnetization is observed even when no external magnetic field is applied to the ferroelectric thin film of Example 1. In other words, the ferroelectric thin film of Example 1 was found to be a multiferroic material having ferromagnetism as well as ferroelectricity described above.

According to the present invention, there can be provided a BFCO film and a BFO film each having an increased amount of remanent polarization. The ferroelectric thin film of the present invention is applicable to an MEMS technology, and does not contaminate the environment. Accordingly, the ferroelectric thin film can be utilized in an instrument that uses a large amount of a ferroelectric material such as a ferroelectric memory, a thin film piezoelectric inkjet head, or an ultrasonic motor without problems.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-229914, filed on Oct. 1, 2009, which is hereby incorporated by reference herein in its entirety.

What is claimed is:

1. A ferroelectric thin film containing a perovskite-type metal oxide formed on a substrate, the ferroelectric thin film comprising multiple columns each formed of a spinel-type metal oxide, the multiple columns being formed in the ferroelectric thin film, wherein each of the columns is in a state of standing in a direction perpendicular to a surface of the substrate, or in a state of slanting at a slant angle in a range of −10° or more to +10° or less with respect to the perpendicular direction.

2. The ferroelectric thin film according to claim 1, wherein a group of the columns is oriented while contacting at a (hk0) plane of the ferroelectric thin film.

3. The ferroelectric thin film according to claim 1, wherein the ferroelectric thin film and a group of the columns are oriented toward a pseudo-cubic (001) plane.

4. The ferroelectric thin film according to claim 1, wherein a group of the columns has an average circle-equivalent diameter of 10 nm or more to 30 nm or less.

5. The ferroelectric thin film according to claim 1, wherein the ferroelectric thin film has a thickness of 50 nm or more to 10,000 nm or less.

6. The ferroelectric thin film according to claim 1, wherein a length in a thickness direction of a group of the columns is equal to or larger than a thickness of the ferroelectric thin film.

7. The ferroelectric thin film according to claim 1, wherein a group of the columns has a surface density of 1×10¹⁴ columns/m² or more to 1×10¹⁵ columns/m² or less.

8. The ferroelectric thin film according to claim 1, wherein a diameter distribution of a group of the columns in a thickness direction is 50% or less.

9. The ferroelectric thin film according to claim 1, wherein the columns are each formed of a compound represented by the following general formula (1):
Co₃₋ₓFeₓO₄ (1)
where x satisfies a relationship of 0≦x≦2.

10. The ferroelectric thin film according to claim 1, wherein the ferroelectric thin film is formed of a compound represented by the following general formula (2):
Bi_{y}(Fe_{1-z}Co_{z})O₃ (2)
where y satisfies a relationship of 0.95≦y≦1.25 and z satisfies a relationship of 0<z≦0.30.

11. The ferroelectric thin film according to claim 1, wherein the ferroelectric thin film is formed of a compound represented by the following general formula (3):
Bi_{y}FeO₃ (3)
where y satisfies a relationship of 0.95≦y≦1.25.
